(19) United States
(12) Patent Application Publication
(10) Pub. No.: US 2012/0298971 A1
(43) Pub. Date: Nov. 29, 2012

(54) ELECTRODE AND ELECTRONIC DEVICE COMPRISING THE SAME

(75) Inventors: Tae-Woo LEE, Pohang-si (KR); Tae-Hee HAN, Incheon (KR); Jong-Hyun AHN, Suwon-si (KR); Youngbin LEE, Pyeongtaek-si (KR); Seong-Hoon WOO, Daegu (KR)

(73) Assignee: POSTECH ACADEMY-INDUSTRY FOUNDATION, Pohang-si (KR)

(21) Appl. No.: 13/478,110

(22) Filed: May 23, 2012

(30) Foreign Application Priority Data
May 27, 2011 (KR) 10-2011-0050844

(51) Int. Cl. H01L 51/00

(52) U.S. Cl. 257/40; 257/E51.039

(57) ABSTRACT

A graphene electrode having a surface modified to have a high work function, and an electronic device including the same.

### CROSS-REFERENCE TO RELATED PATENT APPLICATION

This application claims the benefit of Korean Patent Application No. 10-2011-0050844, filed on May 27, 2011, in the Korean Intellectual Property Office, the disclosure of which is incorporated herein in its entirety by reference.

### BACKGROUND OF THE INVENTION

1. Field of the Invention

The present invention relates to an electrode and an electronic device including the same.

2. Description of the Related Art

Organic light-emitting devices, which are self-emitting devices, have advantages such as a wide viewing angle, excellent contrast, quick response, high luminescence, excellent driving voltage characteristics, and can provide multicolored images.

A conventional organic light-emitting device includes an anode, a cathode, and an organic layer interposed between the anode and the cathode. The organic layer may include an electron injection layer (EIL), a hole transport layer (HTL), an emission layer (EML), an electron transport layer (ETL), and a cathode. When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

Meanwhile, much research into renewable energy has been conducted worldwide. In this regard, organic solar cells have drawn much attention because of their potential of using solar energy as a future energy source. Organic solar cells can more efficiently form a thin film and can be manufactured with low manufacturing costs compared to inorganic solar cells using silicon, and thus can be applied to various flexible devices.

However, mechanical strength, chemical resistance, work function, conductivity, and light transmittance of conventional electrodes are not satisfactory, and thus there is much room for improvement in terms of quality.

### SUMMARY OF THE INVENTION

The present invention provides an electrode having excellent conductivity and high work function.

The present invention also provides an electronic device employing the electrode.

According to an aspect of the present invention, there is provided an electrode including: a graphene-containing layer; and a layer having work function gradient formed on the graphene-containing layer; wherein the layer having work function gradient is a single layer including a first surface that contact with the graphene-containing layer and a second surface that is opposite to the first surface, wherein a work function of the layer having work function gradient gradually increase in a direction from the first surface of the layer having work function gradient to the second surface of the layer having work function gradient.

The graphene may include n sheets, each of which is formed of polycyclic aromatic molecules in which a plurality of carbon atoms are bonded to each other in a covalent bond and extend in a first direction, i.e., a direction parallel to the substrate, i.e., in the X-axis direction or Z-axis direction of FIG. 2, wherein n is an integer of 1 or greater. In this regard, if n is 2 or more, the n sheets are stacked in a second direction, i.e., in a direction perpendicular to the substrate, i.e., in the Y-axis direction of FIG. 2.

The graphene-containing layer may further include a p-type dopant.

A work function of the first surface of the layer having work function gradient may be in the range of 4.8 eV to 5.3 eV, and a work function of the second surface of the layer having work function gradient may be in the range of 5.3 eV to 6.5 eV.

The layer having work function gradient may include a conductive material and a low-surface-energy material.

The low-surface-energy material satisfies as follows: A thin film formed of the low-surface-energy material (e.g., the thin film may have a thickness less than 150 nm) may have a surface energy of 30 mN/m or less and a conductivity in the range of 10⁻¹⁵ to 10⁻¹ S/cm or a thin film formed of a conductive polymeric composition including the low-surface-energy material (e.g., the thin film may have a thickness less than 150 nm) may have a surface energy of 30 mN/m or less and a conductivity in the range of 10⁻⁷ to 10⁻¹ S/cm.

The concentration of the low-surface-energy material may gradually increase in a direction from the first surface, i.e., the surface of the layer having work function gradient contacting the graphene-containing layer (13A of FIG. 1) to the second surface, i.e., the surface of the layer having work function gradient opposite to the first surface (13B of FIG. 1).

Since a work function of the first surface of the layer having work function gradient is the same as that of the conductive material, and an amount of the low-surface-energy material in the second surface is greater than that of the low-surface-energy material in the first surface, the work function of the second surface of the layer having work function gradient may be greater than that of the first surface of the layer having work function gradient.

The low-surface-energy material may include at least one fluorine (F). For example, the low-surface energy material may be a fluorinated polymer or fluorinated oligomer.

The conductive material may include polythiophene, polyaniline, polypyrrole, self-doped polythiophene, self-doped polyaniline, self-doped polypyrrole, or any combination thereof, but is not limited thereto.

According to another aspect of the present invention, there is provided an electronic device including the electrode.

The electronic device may have flexibility.

The electronic device may include an organic light-emitting device, an organic solar cell, an organic memory device, or an organic thin film transistor.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of an electrode according to an embodiment of the present invention;

FIG. 2 is a schematic exploded perspective view of a graphene-containing layer of the electrode according to an embodiment of the present invention;

FIG. 3 schematically shows relationship of work function among the electrode and a layer formed on the electrode;

FIG. 4 is a schematic cross-sectional view of an organic light-emitting device according to an embodiment of the present invention;

FIG. 5 is a schematic cross-sectional view of an organic solar cell according to an embodiment of the present invention;

FIG. 6 is a schematic cross-sectional view of an organic thin film transistor according to an embodiment of the present invention;

FIG. 7 is a graph illustrating optical transmittance of graphene-containing layers of the electrode according to an embodiment of the present invention;

FIG. 8 is a graph illustrating UPS spectrum of graphene-containing layers of the electrode according to an embodiment of the present invention;

FIG. 9 is a graph illustrating molecular concentrations of the electrode with respect to depth;

FIG. 10A is a graph illustrating electric field-current density obtained by dark injection space charge limited current (DI SCLC) transients, and FIG. 10B is a graph illustrating electric field-hole injecting efficiency;

FIG. 11 shows a bent organic light-emitting device according to an embodiment of the present invention;

FIG. 12 is a graph illustrating voltage-current efficiency of an organic light-emitting device according to an embodiment of the present invention;

FIG. 13 is a graph illustrating voltage-power efficiency of an organic light-emitting device according to an embodiment of the present invention;

FIG. 14 is a graph illustrating EL spectrum of an organic light-emitting device according to another embodiment of the present invention; and

FIG. 15 is a graph illustrating voltage-current efficiency of an organic light-emitting device according to another embodiment of the present invention.

### DETAILED DESCRIPTION OF THE INVENTION

Hereinafter, exemplary embodiments of the present invention will be described in detail with reference to the accompanying drawing.

As used herein, the term “and/or” includes any and all combinations of one or more of the associated listed items. Expressions such as “at least one of,” when preceding a list of elements, modify the entire list of elements and do not modify the individual elements of the list.

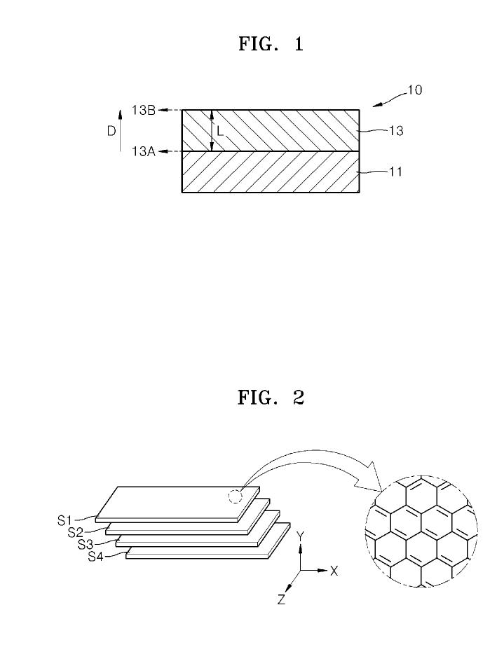

FIG. 1 is a schematic cross-sectional view of an electrode 10 according to an embodiment of the present invention. The electrode 10 includes a graphene-containing layer 11 and a layer having work function gradient 13. The layer having work function gradient 13 includes a first layer 13A that contacts with the graphene-containing layer 11 and a second surface 13B that is opposite to the first surface 13A. The bottom of the graphene-containing layer 11 may contact with a substrate.

The “layer having work function gradient” used herein refers to a layer in which work function has a gradient with respect to depth of the layer.

The graphene-containing layer 11 plays a role of transporting charges, for example, holes. The graphene-containing layer 11 includes graphene.

Even though a solvent that is commonly used in the art is applied to the graphene-containing layer 11, the graphene-containing layer 11 is not substantially dissolved in the solvent. Thus, the graphene has excellent chemical resistance. However, when a general solvent is applied to an indium tin oxide (ITO) electrode that is commonly used in the art, indium and/or oxygen are eluted and move to layers formed on the ITO electrode. When indium and oxygen of the ITO electrode are eluted due to the solvent, interfacial traps are formed on the surface of the ITO electrode, and thus hole injecting efficiency may be reduced. Thus, the ITO electrode cannot provide high hole injecting efficiency to organic light-emitting devices, organic solar cells, and the like which include a polymeric organic layer formed by using a wet process using a solvent.

The graphene may form a thin film and has excellent resistance against mechanical stress. Thus, the graphene has excellent mechanical strength. That is, when external stress is applied to graphene, the graphene may be bent rather than break. Due to flexibility, the graphene may be efficiently applied to flexible electronic devices.

In addition, graphene is a relatively inexpensive material compared to metal used in the ITO electrode, which is relatively expensive.

The graphene may include a plurality of sheets, for example, n sheets, each of which is formed of polycyclic aromatic molecules in which a plurality of carbon atoms are bonded to each other in a covalent bond and extend in a first direction (i.e., a direction parallel to the substrate), wherein n is an integer of 1 or greater.

Here, n may be 1 to 1000, for example, 1 to 100. Alternatively, n may be 1 to 50, or 1 to 10. According to an embodiment of the present invention, n may be 2, 3, or 4, but is not limited thereto. Here, n may vary according to a method of preparing the graphene-containing layer.

FIG. 2 is a schematic exploded perspective view of the graphene-containing layer 11 (n=4) of the electrode according to an embodiment of the present invention; The graphene shown in FIG. 2 includes 4 sheets S1, S2, S3, and S4 of polycyclic aromatic molecules in which a plurality of carbon atoms are bonded to each other in a covalent bond and extend in the first direction. A circle of FIG. 2 shows an expanded view of a portion of the sheets S1, S2, S3, and S4. Each sheet includes polycyclic aromatic molecules in which carbon atoms are bonded to each other in a covalent bond and extend in the first direction, e.g., in the X-axis direction or Z-axis direction. The 4 sheets S1, S2, S3, and S4 are stacked in a direction perpendicular to the first direction, e.g., the Y-axis direction.

The graphene-containing layer may further include a p-type dopant that may improve conductivity and reduce sheet resistance. The p-type dopant may be metal particles, various substituents, or the like. For example, the p-type dopant may include HNO₃, AuCl₃, HCl, nitromethane, H₂SO₄, HAuCl₄, 2,3-dichloro-5,6-dicyanobenzoquinone, acid-terminated small molecules, such as 3-mercaptopropionic acid, 16-mercaptohexadecanoic acid, benzosulfonic acid, and benzene phosphonic acid, a polymeric acid, such as polystyrene sulfonic acid, but is not limited thereto.

In FIG. 1, the layer having work function gradient 13 may have work function that changes with respect to the depth L of the layer having work function gradient 13. For example, the layer having work function gradient 13 has a gradient of work function that increases in a direction D from the first surface 13A to the second direction 13B. By using the layer having work function gradient 13, hole injection barrier between layers formed on the layer having work function gradient 13 and the graphene-containing layer 11 may be lowered.

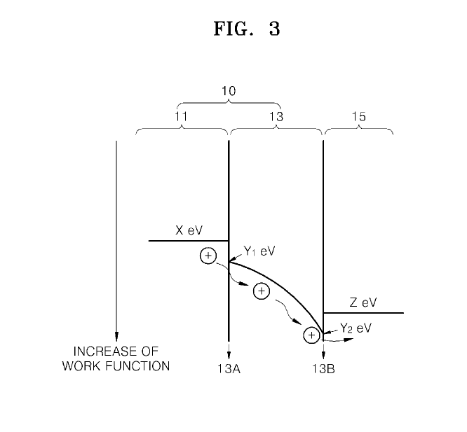

FIG. 3 schematically shows relationship of work function among the electrode 10 and a layer 15 formed on the layer having work function gradient 13.

A work function of the graphene-containing layer 11 of the electrode 10 is X eV. The X may be, for example, a real number in the range of 4.0 to 4.7, but is not limited thereto.

Meanwhile, as shown in FIG. 3, the work function of the layer having work function gradient 13 gradually increases in the direction from the first surface 13A to the second surface 13B of the layer having work function gradient 13. A work function of the first surface 13A of the layer having work function gradient 13 is Y₁ eV, and a work function of the second surface 13B is Y₂ eV, wherein Y₁<Y₂. Accordingly, hole mobility between the graphene-containing layer 10 and the layer 15 may be improved. In addition, if the electrode 10 is used as an anode of an organic light-emitting device, electrons may be efficiently prevented from flowing into the graphene-containing layer 11 via the layer 15 by the layer having work function gradient 13.

A work function of the layer 15 formed on the layer having work function gradient 13 is Z eV. The layer 15 may vary according to the types of electronic devices including the electrode 10. For example, if the electronic device including the electrode 10 is an organic light-emitting device, the layer 15 may be a hole transport layer, and various modifications may be available. Here, Z may be a real number in the range of 5.4 to 5.6, but is not limited thereto.

For example, the work function X of the graphene-containing layer 11 and the work function Y₁ of the first surface 13A of the layer having work function gradient 13 may have a relationship of X≦Y₁. In addition, the work function Y₂ of the second surface 13B of the layer having work function gradient 13 and the work function Z of the layer 15 may have a relationship of Z≦Y₂, but is not limited thereto.

The work function Y₁ of the first surface 13A of the layer having work function gradient 13 may be in the range of 4.8 to 5.3, for example, 5.0 to 5.2. The work function Y₂ of the second surface 13B of the layer having work function gradient 13 may be in the range of 5.3 to 5.3, for example, 5.7 to 6.0, but is not limited thereto.

The layer having work function gradient 13 may include a conductive material and a low-surface-energy material.

The “low-surface-energy material” used herein refers to a material capable of forming a film having a low surface energy, particularly, a material having a lower surface energy than the conductive material.

The low-surface-energy material includes at least one fluorine (F) and may have higher hydrophobicity than the conductive material. In addition, the low-surface-energy material may be a material capable of providing higher work function than the conductive material. For example, the low-surface-energy material satisfies as follows: a thin film formed of the low-surface-energy material (e.g., the thin film may have a thickness less than 150 nm) may have a surface energy of 30 mN/m or less and a conductivity in the range of 10⁻¹⁵ to 10⁻¹ S/cm. In addition, a thin film formed of a conductive polymer composition including the low-surface-energy material (e.g., the thin film may have a thickness less than 150 nm) may have a surface energy of 30 mN/m or less and a conductivity in the range of 10⁻⁷ to 10⁻¹ S/cm.

Thus, when a layer including the mixture of the conductive material and the low-surface-energy material is formed, the conductive material and the low-surface-energy material cannot be homogeneously mixed with each other due to low surface energy of the low-surface-energy material. Instead, the conductive material and the low-surface-energy material may be distributed such that the concentration of the low-surface-energy material gradually increases in a direction from the first surface 13A to the second surface 13B, and relatively, the concentration of the conductive material gradually increases in a direction from the second surface 13B to the first surface 13A. Thus, the layer having work function gradient 13 may have a gradient of work function.

Since the layer having work function gradient 13 is formed through self-arrangement of the conductive material and the low-surface-energy material, it has a single layered structure in which a boundary between the conductive material layer and the low-surface-energy material layer is not recognizable.

A work function of the first surface 13A of the layer having work function gradient 13 may be equal to that of the conductive material, and a work function of the second surface 13B of the layer having work function gradient 13 may be equal to that of the low-surface-energy material, but they are not limited thereto.

The low-surface-energy material may be a material that has a solubility of 90% or more, for example, 95% or more, in a polar solvent. Examples of the polar solvent include water, alcohol, dimethylformamide (DMF), dimethylsulfoxide (DMSO), acetone, and the like, but are not limited thereto.

The low-surface-energy material may include at least one fluorine (F). For example, the low-surface-energy material may be a fluorinated polymer or a fluorinated oligomer having at least one fluorine (F).

According to an embodiment of the present invention, the low-surface-energy material may be a fluorinated polymer having a repeating unit represented by one of Formulae 1 to 3 below.

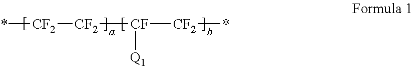

In Formula 1, a is a number from 0 to 10,000,000;

b is a number from 1 to 10,000,000; and

Q₁ is —[O—C(R₁)(R₂)—C(R₃)(R₄)]_{c}[OCF₂CF₂]_{d}—R₅, —COOH, or —O—R_{f}—R₆;

wherein R₁, R₂, R₃ and R₄ are each independently —F, —CF₃, —CHF₂ or —CH₂F;

c and d are each independently a number from 0 to 20;

R_{f} is —(CF₂)_{z}— or —(CF₂CF₂O)_{z}—CF₂CF₂—, wherein z is an integer from 1 to 50; and

R₅ and R₆ are each independently —SO₃M, —PO₃M₂, or —CO₂M;

wherein M is Na⁺, K⁺, Li⁺, H⁺, CH₃(CH₂)_{w}NH₃⁺, NH₄⁺, NH₂⁺, NHSO₂CF₃⁺, CHO⁺, C₂H₅OH⁺, CH₃OH⁺, or CH₃(CH₂)_{w}CHO⁺, wherein w is an integer from 0 to 50.

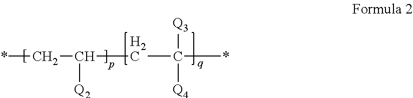

In Formula 2, Q₂ is a hydrogen atom, a substituted or unsubstituted C₅-C₅₀ aryl group, or —COON;

Q₃ is a hydrogen atom or a substituted or unsubstituted C₁-C₂₀ alkyl group;

Q₄ is —O— (CF₂)ᵣSO₃M, —O—(CF₂)ᵣ—PO₃M₂, —O—(CF₂)ᵣ—CO₂M, or —CO—NH—(CH₂)ₛ—(CF₂)ₜ—CF₃,

wherein r, s and t are each independently a number from 0 to 20; and

wherein M is Na⁺, K⁺, Li⁺, H⁺, CH₃(CH₂)_{w}NH₃⁺, NH₄⁺, NH₂⁺, NHSO₂CF₃⁺, CHO⁺, C₂H₅OH⁺, CH₃OH⁺, or CH₃(CH₂)_{w}CHO⁺, wherein w is an integer from 0 to 50.

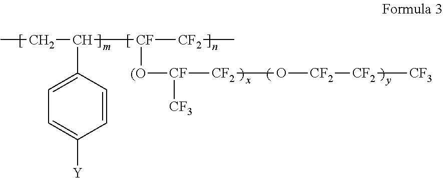

In Formula 3, 0≦m<10,000,000, and 0<n≦10,000,000;

x and y are each independently a number from 0 to 20; and

Y is —SO₃M, —PO₃M₂, or —CO₂M;

wherein M is Na⁺, K⁺, Li⁺, H⁺, CH₃(CH₂)_{w}NH₃⁺, NH₄⁺, NH₂⁺, NHSO₂CF₃⁺, CHO⁺, C₂H₅OH⁺, CH₃OH⁺, or CH₃(CH₂)_{w}CHO⁺, wherein w is an integer from 0 to 50.

For example, the low-surface-energy material may be a fluorinated polymer including a repeating unit represented by Formula 1, but is not limited thereto.

For example, the low-surface-energy material may be a fluorinated polymer including a repeating unit represented by Formula 1, wherein a is a number from 100 to 10000, b is a number from 50 to 1000, and Q₁ is —[O—C(R₁)(R₂)—C(R₃)(R₄)]_{c}—[OCF₂CF₂]_{d}—R₅.

For example, the low-surface-energy material may be a fluorinated polymer including a repeating unit represented by Formula 1, wherein a is a number from 100 to 10000, b is a number from 50 to 1000, Q₁ is —[O—C(R₁)(R₂)—C(R₃)(R₄)]_{c}—[OCF₂CF₂]_{d}—R₅, wherein c is a number from 1 to 3, R₁, R₂ and R₃ are —F, R₄ is —CF₃, d is a number from 1 to 3, and R₅ is —SO₃M, but is not limited thereto.

Meanwhile, the low-surface-energy material may be a silane fluoride-based material represented by Formula 10 below.

X-M^{f}ₙ-M^{h}ₘ-M^{a}ᵣ-(G)ₚ Formula 10

In Formula 10, X is a terminal group;

M^{f} is a unit derived from a fluorinated monomer prepared by condensation reaction of perfluoropolyether alcohol, polyisocyanate, and an isocyanate reactive-non-fluorinated monomer or a fluorinated C₁-C₂₀ alkylene group;

M^{h} is a unit derived from a non-fluorinated monomer;

M^{a} is a unit having a silyl group represented by —Si(Y₄)(Y₅)(Y₆),

wherein, Y₄, Y₅ and Y₆ are each independently a halogen atom, a substituted or unsubstituted C₁-C₂₀ alkyl group, a substituted or unsubstituted C₆-C₃₀ aryl group, or a hydrolysable substituent, wherein at least one of the Y₄, Y₅ and Y₆ is a hydrolysable substituent,

G is a monovalent organic group including a chain transfer agent;

n is a number from 1 to 100,

m is a number from 0 to 100,

r is a number from 0 to 100,

wherein n+m+r≧2, and

p is a number from 0 to 10.

For example, X may be a halogen atom, M^{f} may be a fluorinated C₁-C₁₀ alkylene group, M^{h} may be a C₂-C₁₀ alkylene group, Y₄, Y₅ and Y₆ may be each independently a halogen atom (Br, Cl, F, or the like), and p may be 0. For example, the silane fluoride-based material represented by Formula 10 may be CF₃CH₂CH₂SiCl₃, but is not limited thereto.

The silane fluoride-based material represented by Formula 10 is described in U.S. Pat. No. 7,728,098, the disclosure of which is incorporated herein in its entirety by reference.

The conductive material may be, for example, any known conductive polymer.

For example, the conductive material may include polythiophene, polyaniline, polypyrrole, polystyrene, sulfonated polystyrene, poly(3,4-ethylenedioxythiophene), self-doped conductive polymer, and any derivative and combination thereof. The derivative may include various sulfonic acids.

For example, the conductive material may include polyaniline/dodecylbenzenesulfonic acid (Pani:DBSA, refer to the following formula), poly(3,4-ethylenedioxythiophene)/poly(4-styrenesulfonate) (PEDOT:PSS, refer to the following formula), polyaniline/camphor sulfonicacid (Pani:CSA), or polyaniline/poly(4-styrenesulfonate) (PANI:PSS), but is not limited thereto.

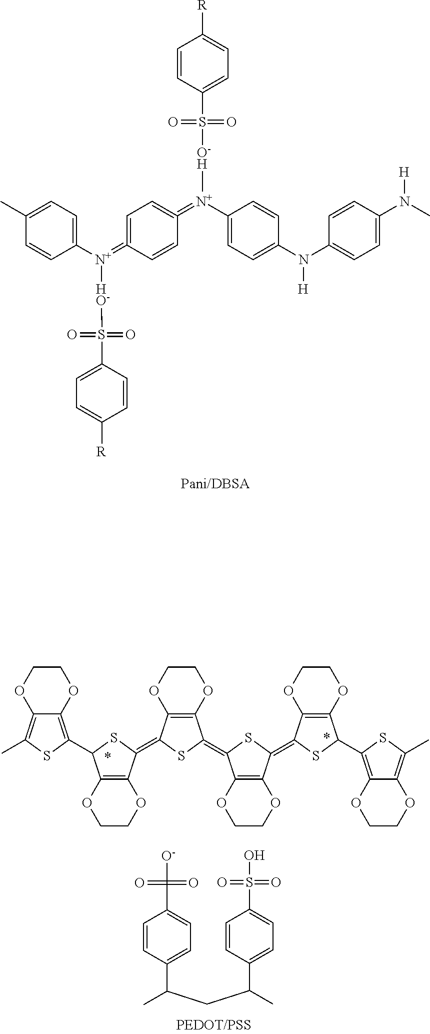

Here, R may be H or a C₁-C₁₀ alkyl group.

The self-doped conductive polymer may have a degree of polymerization in the range of 10 to 10,000,000 and may include a repeating unit represented by Formula 13 below.

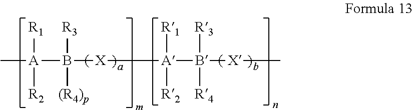

In Formula 13, 0<m<10,000,000, 0<n<10,000,000, 0≦a≦20, and 0≦b≦20;

at least one of R₁, R₂, R₃, R′₁, R′₂, R′₃ and R′₄ includes an ionic group, and A, B, A′, and B′ are each independently selected from the group consisting of C, Si, Ge, Sn, and Pb;

R₁, R₂, R₃, R′₁, R′₂, R′₃ and R′₄ are each independently selected from the group consisting of a hydrogen atom, a halogen atom, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group, wherein a hydrogen atom or a halogen atom is selectively adhered to carbon of the repeating unit of Formula 13;

R₄ is a conjugated conductive polymer chain; and

X and X′ are each independently selected from the group consisting of a single bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, and a substituted or unsubstituted C₅-C₃₀ heterocycloalkylene, wherein a hydrogen atom or a halogen atom is selectively adhered to carbon of the repeating unit of Formula 13.

For example, the ionic group may include an anionic group selected from the group consisting of PO₃²⁻, SO₃, COO⁻, I⁻, and CH₃COO⁻, a metal ion selected from the group consisting of Na⁺, K⁺, Li⁺, Mg⁺², Zn⁺², and Al⁺³, and an organic ion selected from the group consisting of H⁺, NH₄⁺, and CH₃(—CH₂—)ₙO⁺, wherein n is a natural number from 1 to 50. The ionic group may further include a cationic group matching the anionic group.

For example, in the self-doped conductive polymer of Formula 13, at least one of R₁, R₂, R₃, R′₁, R′₂, R′₃, and R′₄ may be fluorine or a group substituted with fluorine, but is not limited thereto.

Examples of the unsubstituted alkyl group include a linear or branched alkyl group, such as methyl, ethyl, propyl, isobutyl, sec-butyl, tert-butyl, pentyl, iso-amyl, and hexyl. One or more hydrogen atoms in the alkyl group may be substituted with a halogen atom, a hydroxy group, a nitro group, a cyano group, a substituted or unsubstituted amino group (—NH₂, —NH(R), or —N(R′)(R″), wherein R′ and R″ are each independently a C₁-C₁₀ alkyl group), an amidino group, hydrazine, hydrazone, a carboxyl group, a sulfonic acid group, a phosphoric acid group, a C₁-C₂₀ alkyl group, a C₁-C₂₀ halogenated alkyl group, a C₁-C₂₀ alkenyl group, a C₁-C₂₀ alkynyl group, a C₁-C₂₀ heteroalkyl group, a C₆-C₂₀ aryl group, a C₆-C₂₀ arylalkyl group, a C₆-C₂₀ heteroaryl group, or a C₆-C₂₀ heteroarylalkyl group.

The heteroalkyl group is a radical formed as a result of replacing one or more carbon atoms, for example, 1 to 5 carbon atoms, of the main chain of the alkyl group with a hetero atom such as O, S, N, or P.

The aryl group refers to a carbocyclic aromatic system including one or more aromatic rings, the rings being attached or fused together through a pendent process. Examples of the aryl group include an aromatic group such as phenyl, naphthyl, and tetrahydronaphthyl. One of more hydrogen atoms of the aryl group may be substituted with the same substituent as in the alkyl group.

The heteroaryl group refers to a 5 to 30-membered aromatic ring system having 1, 2, or 3 heteroatoms selected from the group consisting of N, O, P, and S with the remaining ring atoms being C, wherein the rings may be attached or fused together through a pendent process. Further, one or more hydrogen atoms of the heteroaryl group may be substituted with the same substituent as in the alkyl group.

The alkoxy group refers to a radical-O-alkyl, wherein the alkyl is as defined above. Examples of the alkoxy group include methoxy, ethoxy, propoxy, isobutyloxy, sec-butyloxy, pentyloxy, iso-amyloxy, and hexyloxy. One or more hydrogen atoms of the alkoxy group may be substituted with the same substituent as in the alkyl group.

The heteroalkoxy group refers to the alkoxy group in which at least one heteroatom, for example, O, S, or N, is present in an alkyl chain, and examples of the heteroalkoxy group include CH₃CH₂OCH₂CH₂O—, C₄H₉OCH₂CH₂OCH₂CH₂O—, and CH₃—O—(CH₂CH₂O)ₙH.

The arylalkyl group refers to a radical formed as a result of replacing some of the hydrogen atoms of the aryl group defined above with a lower alkyl group, for example, methyl, ethyl, propyl, and the like. For example, the arylalkyl group may be benzyl, phenylethyl, and the like. One or more hydrogen atoms of the arylalkyl group may be substituted with the same substituent as in the alkyl group.

The heteroarylalkyl group refers to a radical formed as a result of replacing some of the hydrogen atoms of the heteroaryl group with a lower alkyl group. In the heteroarylalkyl group, the heteroaryl group is as defined above. One or more hydrogen atoms of the heteroaryl alkyl group may be substituted with the same substituent as in the alkyl group.

The aryloxy group refers to a radical-O-aryl, wherein the aryl is as defined above. Examples of the aryloxy group include phenoxy, naphthoxy, antracenyloxy, phenantrenyloxy, fluorenyloxy, and indenyloxy. One or more hydrogen atoms of the aryloxy group may be substituted with the same substituent as in the alkyl group.

The heteroaryloxy group refers to a radical-O-heteroaryl, wherein the heteroaryl is as defined above.

Examples of the heteroaryloxy group include benzyloxy and phenylethyloxy. One or more hydrogen atoms of the heteroaryloxy group may be substituted with the same substituent as in the alkyl group.

The cycloalkyl group refers to a monovalent monocyclic system having 5 to 30 carbon atoms. One or more hydrogen atoms of the cycloalkyl group may be substituted with the same substituent as in the alkyl group.

The heterocycloalkyl group refers to a 5 to 30-membered monovalent monocyclic system having 1, 2 or 3 heteroatoms selected from N, O, P or S with the remaining ring atom being C. One or more hydrogen atoms of the heterocycloalkyl group may be substituted with the same substituent as in the alkyl group.

The alkylester group refers to a functional group in which the alkyl group is combined with the ester group, wherein the alkyl group is as defined above.

The heteroalkyl ester group refers to a functional group in which the heteroalkyl group is combined with the ester group, wherein the heteroalkyl group is as defined above.

The arylester group refers to a functional group in which the aryl group is combined with the ester group, wherein the aryl group is as defined above.

The heteroaryl ester group refers to a functional group in which the heteroaryl group is combined with the ester group, wherein the heteroaryl group is as defined above.

The amino group used herein refers to —NH₂, —NH(R), or —N(R′)(R″), wherein R′ and R″ are each independently a C₁-C₁₀ alkyl group.

The halogen atom may be fluorine, chlorine, bromine, iodine, or astatine, for example, fluorine.

The total content of the low-surface-energy material in the layer having work function gradient 13 may be in the range of 250 parts by weight to 450 parts by weight, for example, 300 parts by weight to 400 parts by weight, based on 100 parts by weight of the conductive material, but is not limited thereto. If the content of the low-surface-energy material is within the range described above, the layer having work function gradient 13 may have an efficient gradient of work function.

The thickness of the electrode 10 may be in the range of 10 nm to 150 nm, for example, 50 nm to 80 nm. If the thickness of the electrode 10 is within the range described above, the electrode 10 may have excellent work function and flexibility characteristics.

A method of preparing the electrode 10 may include: forming a graphene-containing layer 11 on a substrate; and forming a layer having work function gradient 13 on the graphene-containing layer 11.

First, the substrate may be any substrate that is commonly used in a semiconductor process. For example, the substrate may include silicon, silicon oxide, metal foil, e.g., copper foil and aluminum foil, and stainless steel, metal oxide, a polymer substrate, and any combination of at least two thereof. The metal foil may be formed of a material having a high melting point and not functioning as a catalyst for forming graphene. The metal oxide may include aluminum oxide, molybdenum oxide, and indium tin oxide, and the polymer substrate may include kapton foil, polyethersulphone (PES), polyacrylate (PAR), polyetherimide (PEI), polyethylene naphthalate (PEN), polyethyleneterepthalate (PET), polyphenylene sulfide (PPS), polyallylate, polyimide, polycarbonate (PC), cellulose triacetate (TAC), cellulose acetate propinonate (CAP), and the like, but is not limited thereto.

For example, the substrate may be the polymer substrate as described above, but is not limited thereto.

Then, the graphene-containing layer 11 is formed on the substrate by directly growing graphene on the substrate; by using a method including applying a solvent and graphene or a graphene precursor on the substrate and removing the solvent; by using a method including forming graphene on a base substrate and transferring the graphene onto the substrate; or various methods. If required, a graphene-doping process may further be performed. The graphene-doping process may be performed by contacting a dopant such as HNO₃, AuCl₃, HCl, nitromethane, H₂SO₄, HAuCl₄, 2,3-dichloro-5,6-dicyanobenzoquinone, acid-terminated small molecules, such as 3-mercaptopropionic acid, 16-mercaptohexadecanoic acid, benzosulfonic acid, and benzene phosphonic acid, a polymeric acid, such as polystyrene sulfonic acid, or a precursor thereof with graphene, and performing a heat-treatment. As a result, a doped graphene-containing layer may be obtained.

Then, optionally, surface-treatment may be conducted by using UV rays, ozone, oxygen plasma, and the like.

Then, the layer having work function gradient 13 is formed on the graphene-containing layer 11. The layer having work function gradient 13 may be formed by applying a mixture including the conductive material, the low-surface-energy material, and the solvent on the graphene-containing layer 11, and heat-treating the mixture.

For example, the layer having work function gradient 13 is not formed by respectively forming the conductive material layer and the low-surface-energy material layer. Instead, the layer having work function gradient 13 is formed by using one layer-forming process including applying the mixture including the conductive material, the low-surface-energy material, and the solvent to the graphene-containing layer 11 and heat-treating the mixture since the conductive material and the low-surface-energy material are self-arranged to form a concentration gradient due to surface energy difference. Accordingly, the manufacturing process thereof is simple. Thus, the method of forming the layer having work function gradient may be efficiently employed in the preparation of large-area electronic devices.

The electrode may be applied to various electronic devices. The electrode has flexibility, which is distinguished from the ITO electrode. Thus, flexible electronic devices may be manufactured by using a flexible substrate. Thus, the electronic devices may have flexibility. The flexible substrate may be the polymer substrate described above, but is not limited thereto.

The electronic devices may be devices having various known structures and performing various functions, for example, organic light-emitting devices, organic solar cells, organic memory devices, or organic thin film transistors.

The electronic devices may be used in various electronic apparatuses such as display apparatuses, lighting lamps, and semiconductor chips.

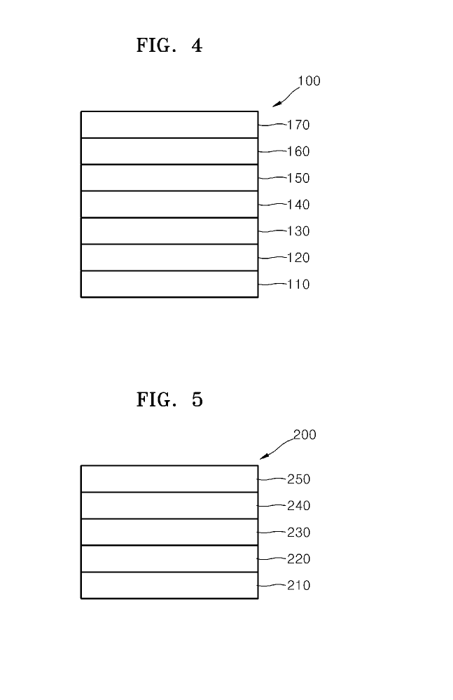

FIG. 4 is a schematic cross-sectional view of an organic light-emitting device 100 including the electrode. The organic light emitting device 100 of FIG. 4 includes a substrate 110, a first electrode 120, a hole transport layer (HTL) 130, an emission layer (EML) 140, an electron transport layer (ETL) 150, an electron injection layer (EIL) 160, and a second electrode 170. When a voltage is applied between the first electrode 120 and the second electrode 170 of the organic light-emitting device 100, holes injected from the first electrode 120 move to the EML 140 via the HTL 130, and electrons injected from the second electrode 170 move to the EML 140 via the ETL 150 and the EIL 160. The holes and electrons recombine in the EML 140 to generate excitons. When the excitons drop from an excited state to a ground state, light is emitted. The substrate 110 may be disposed under the first electrode 120.

The substrate 110 may be the substrate described above. For example, the substrate 110 may be a flexible substrate, e.g., a polymer substrate as described above.

The first electrode 120 includes the graphene-containing layer and the layer having work function gradient. The first layer 120 may function as a hole injecting electrode.

The organic light-emitting device 100 may not include a hole injection layer (HIL). This is because holes may be efficiently injected into the HTL 130 by the layer having work function gradient of the first electrode 120. Thus, the layer having work function gradient of the first electrode 120 may contact with the HTL 130.

The HTL 130 may be formed by using any known method selected from the group consisting of vacuum deposition, spin-coating, casting, LB technique, or the like. When the HTL 130 is formed by using vacuum deposition, deposition conditions may vary according to a compound that is used to form the HTL 130, and the structure and thermal properties of the HTL 130 to be formed. For example, conditions for vacuum deposition may include a deposition temperature ranging from 100 to 500° C., a pressure ranging from 10⁻¹⁰ to 10⁻³ torr, and a deposition velocity ranging from 0.01 to 100 Å/sec. Meanwhile, when the HTL 130 is formed by using spin-coating, coating conditions may vary according to a compound that is used to form the HTL 130, and the structure and thermal properties of the HTL 130 to be formed. For example, however, conditions for the spin-coating may include the coating speed ranging from 2000 to 5000 rpm, and a heat-treatment temperature for removing a solvent after coating ranging from 80 to 200° C.

A material used to form the HTL 130 may be any known hole transporting material. Examples of the material include an amine derivative having an aromatic condensation ring such as N,N′-di(1-naphthyl)-N,N′-diphenylbenzidine (NPB), N-phenylcarbazole, and N,N′-bis(3-methylphenyl)-N,N′-diphenyl-[1,1-biphenyl]-4,4′-diamine (TPD), and a triphenylamine-based material such as 4,4′,4″-tris(N-carbazolyl)triphenylamine (TCTA). Among these materials, TCTA may not only transport holes but also inhibit excitons from being diffused from the EML 140.

The thickness of the HTL 130 may be in the range of 5 to 100 nm, for example, 10 to 60 nm. When the thickness of the HTL 130 is within this range, the HTL 130 may have excellent hole transporting properties without an increase in driving voltage.

The EML 140 may be formed by using any known method selected from the group consisting of vacuum deposition, spin-coating, casting, LB technique, or the like. In this regard, the deposition and coating conditions may be similar to those for the formation of the HTL 130, although the deposition and coating conditions may vary according to a compound that is used to form the EML 140, and the structure and thermal properties of the EML 140 to be formed.

The EML 140 may be formed of a single emitting material or may include a host and a dopant.

Examples of the host include Alq₃, 4,4′-N,N′-dicarbazole-biphenyl (CBP), 9,10-di(naphthalene-2-yl)anthracene (ADN), TCTA, 1,3,5-tris(N-phenylbenzimidazole-2-yl)benzene (TPBI), 3-tert-butyl-9,10-di(naphtha-2-yl)anthracene (TBADN), E3 (refer to the following formula), and BeBq₂ (refer to the following formula), but are not limited thereto. If desired, NPB that is a material used to form the HTL 130 may also be used as a host.

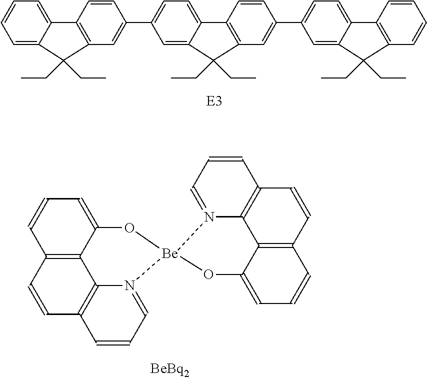

Meanwhile, examples of known red dopants include rubrene(5,6,11,12-tetraphenylnaphthacene (PtOEP), Ir(piq)₃, and Btp₂₁r(acac), but are not limited thereto.

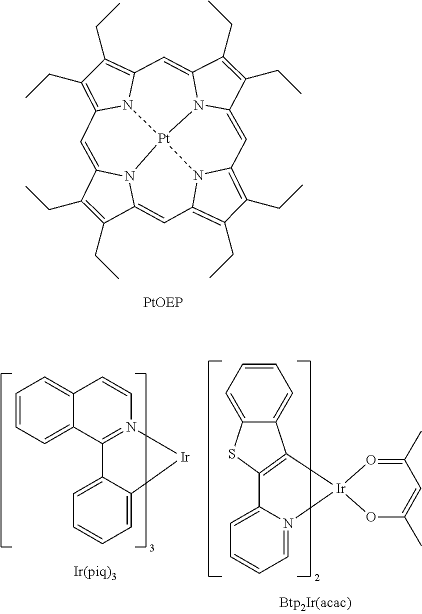

Examples of known green dopants include, but are not limited to, Ir(ppy)₃ (ppy=phenylpyridine), Ir(ppy)₂(acac), Ir(mpyp)₃, and 10-(2-benzothiazolyl)-1,1,7,7-tetramethyl-2,3,6,7-tetrahydro-1H,5H,11H-[1]benzopyropyrano[6,7-8-i,j]quinolizine-11-on (C545T, refer to the following formula.

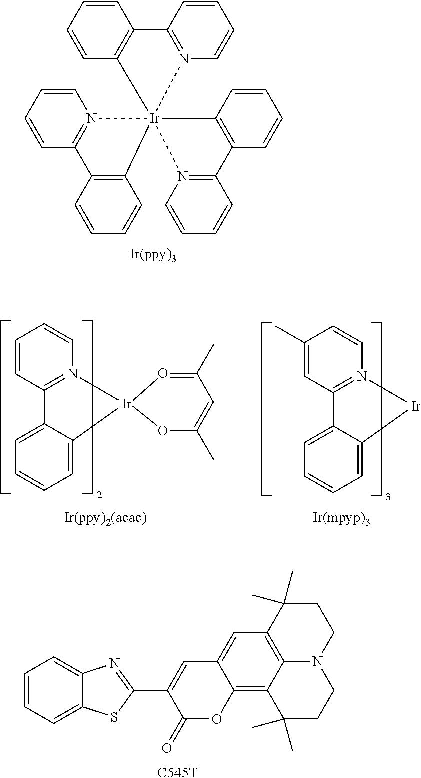

Meanwhile, examples of known blue dopants include F₂Irpic, (F₂ppy)₂Ir(tmd), Ir(dfppz)₃, ter-fluorene, 4,4′-bis(4-di-p-tolylaminostyryl)biphenyl (DPAVBi), and 2,5,8,11-tetra-t-butyl pherylene (TBP), but are not limited thereto.

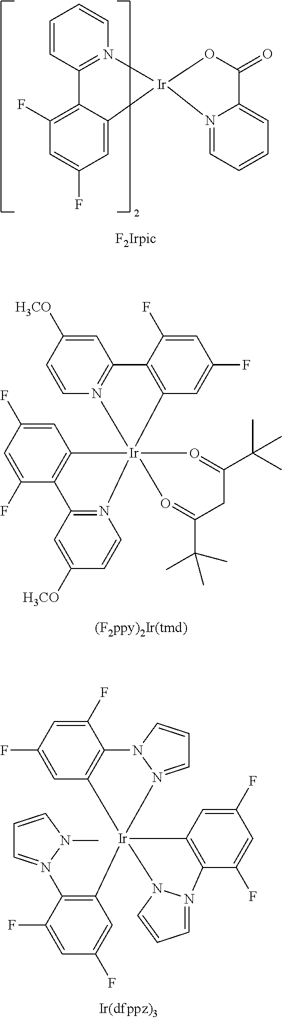

The thickness of the EML 140 may be in the range of 10 to 100 nm, for example, 10 to 60 nm. When the thickness of the EML 140 is within the range described above, the EML 140 may have excellent light-emitting characteristics without an increase in driving voltage.

A hole blocking layer (HBL, not shown in FIG. 4) prevents diffusion of triplet excitons or holes of the EML 140 (if, the EML 140 includes a phosphorescent compound) into the second electrode 70. The HBL may be formed on the EML 140 by using any known method such as vacuum deposition, spin-coating, casting, and LB technique. In this regard, the deposition and coating conditions may be similar to those for the formation of the HTL 130, although the deposition and coating conditions may vary according to a compound that is used to form the HBL, and the structure and thermal properties of the HBL to be formed.

A hole blocking material may be any known hole blocking material. For example, oxadiazole derivatives, triazole derivatives, and phenanthroline derivatives may be used to form the HBL.

The thickness of the HBL may be in the range of about 5 nm to about 100 nm, for example, about 10 nm to about 30 nm. When the thickness of the HBL is within the range described above, the HBL may have excellent hole blocking properties without an increase in driving voltage.

The ETL 150 may be formed by using any known method selected from the group consisting of vacuum deposition, spin-coating, casting, LB technique, or the like. In this regard, the deposition and coating conditions may be similar to those for the formation of the HIL 120, although the deposition and coating conditions may vary according to a compound that is used to form the ETL 150, and the structure and thermal properties of the ETL 150 to be formed.

A material used to form the ETL 150 may be any known electron transporting material, for example, tris(8-quinolinorate)aluminum (Alq₃), TAZ, 4,7-diphenyl-1,10-phenanthroline (Bphen), BCP, BeBq₂, and BAlq.

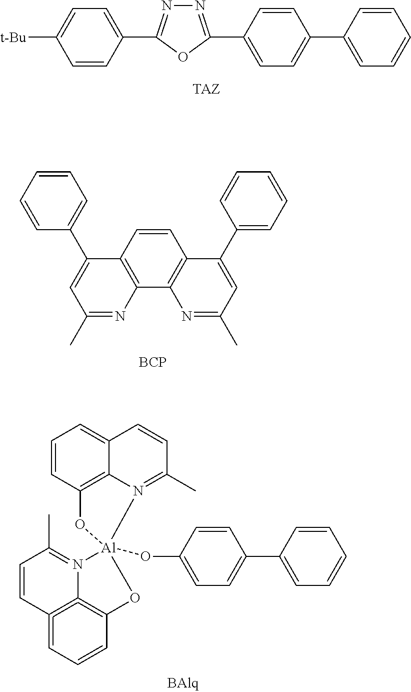

The thickness of the ETL 150 may be in the range of about 10 to about 100 nm, for example, about 20 to about 50 nm. When the thickness of the ETL 150 is within the range described above, the ETL 150 may have excellent electron transporting properties without an increase in driving voltage.

The EIL 160 may be formed on the ETL 150. A material used to form the EIL 160 may be any known electron injecting material such as LiF, NaCl, CsF, Li₂O, BaO, BaF₂, and lithium quinolate (Liq). The deposition conditions may be similar to those for the formation of the HTL 130, although the deposition conditions may vary according to a compound that is used to form the EIL 160.

The thickness of the EIL 160 may be in the range of about 0.1 nm to about 10 nm, for example in the range of about 0.5 nm to about 5 nm. When the thickness of the EIL 160 is within the range described above, the EIL 160 may have satisfactory electron injecting properties without an increase in driving voltage.

The second electrode 170 may be a cathode, which is an electron injecting electrode. Metal, an alloy, an electrically conductive compound, or any combination thereof, which have a relatively low work function, may be used to form the second electrode 250. In this regard, the second electrode 250 may be formed of lithium (Li), magnesium (Mg), aluminum (Al), aluminum (Al)-lithium (Li), calcium (Ca), magnesium (Mg)-indium (In), magnesium (Mg)-silver (Ag), or the like. ITO, IZO, or the like may also be used to prepare a top-emission type light-emitting diode.

The organic light-emitting device 100 may have very high hole injecting efficiency by using the electrode as an anode, and may have excellent electrical characteristics by preventing electrons from being injected into the first electrode 120 via the HTL 130, and may have flexibility by using a flexible substrate as the substrate 110.

FIG. 5 is a schematic cross-sectional view of an organic solar cell 200 including the electrode.

The organic solar cell 200 of FIG. 5 includes a substrate 210, a first electrode 220, a heteroadhesive layer 230, an electron accepting layer 240, and a second electrode 250. Light arrives at the organic solar cell 200 splits into holes and electrons in the heteroadhesive layer 230. The electrons move to the second electrode 250 via the electron accepting layer 240, and the holes move to the first electrode 220.

The substrate 210 is defined as described above with reference to the substrate 110. Meanwhile, the first electrode 220 may be as defined above.

The heteroadhesive layer 230 may include a material capable of splitting light into holes and electrons. For example, the heteroadhesive layer 230 may include a p-type organic semiconductor material or an n-type organic semiconductor material. For example, the heteroadhesive layer 230 may include poly(3-hexylthiophene) and phenyl-C61-butyric acid methyl ester (PCMB), but is not limited thereto.

The electron accepting layer 240 may include a material capable of accepting electrons, for example, the material used to form the EIL 160 of the organic light-emitting diode 100 as described above.

The second electrode 250 may be a cathode, which is an electron injecting electrode. Metal, an alloy, an electrically conductive compound, or any combination thereof, which have a relatively low work function, may be used to form the second electrode 250. In this regard, the second electrode 250 may be formed of lithium (Li), magnesium (Mg), aluminum (Al), aluminum (Al)-lithium (Li), calcium (Ca), magnesium (Mg)-indium (In), magnesium (Mg)-silver (Ag), or the like.

Since the organic solar cell 200 includes the electrode 220, holes generated in the heteroadhesive layer 230 may efficiently move to the electrode 220. Thus, excellent electrical characteristics may be obtained.

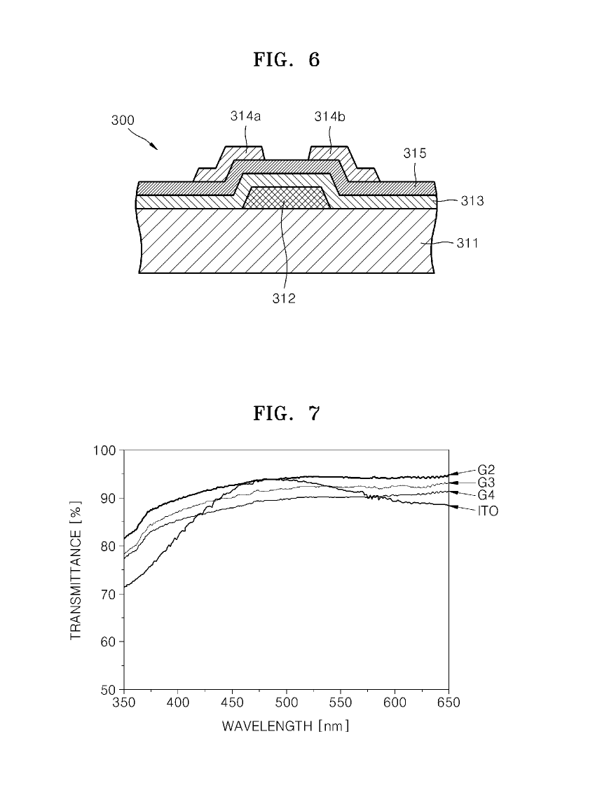

FIG. 6 is a schematic cross-sectional view of an organic thin film transistor 300 including the electrode.

The organic thin film transistor 300 of FIG. 6 includes a substrate 311, a gate electrode 312, an insulating layer 313, an organic semiconductor layer 315, and source and drain electrodes 314a and 314b. At least one of the gate electrode 312 and the source and drain electrodes 314a and 314b may be the electrode as described above.

The substrate 311 is defined as described above with reference to the substrate 110.

The gate electrode 312 having a predetermined pattern is formed on the substrate 311. The gate electrode 312 may be formed of a metal such as gold (Au), silver (Ag), copper (Cu), nickel (Ni), platinum (Pt), palladium (Pd), aluminum (Al), and molybdenum (Mo), or a metal alloy such as Al:Nd and Mo:W, but is not limited thereto.

The insulating layer 313 is formed on the gate electrode 312 to cover the gate electrode 312. The insulating layer 313 may include an inorganic material such as a metal oxide or metal nitride, an organic material such as a flexible organic polymer, or various other materials.

The organic semiconductor layer 315 is formed on the insulating layer 313. The organic semiconductor layer 315 may include pentacene, tetracene, anthracene, naphthalene, α-6-thiophene, α-4-thiophene, perylene and derivatives thereof, rubrene and derivatives thereof, coronene and derivatives thereof, perylene tetracarboxylic diimide and derivatives thereof, perylene tetracarboxylic dianhydride and derivatives thereof, polythiophene and derivatives thereof, poly(p-phenylene vinylene) and derivatives thereof, poly(p-phenylene) and derivatives thereof, polyfluorene and derivatives thereof, polythiophenevinylene and derivatives thereof, polythiophene-hetero ring aromatic copolymer and derivatives thereof, oligoacene of naphthalene and derivatives thereof, oligothiophene of α-5-thiophene and derivatives thereof, phthalocyanine containing or not containing a metal and derivatives thereof, pyromellitic dianhydride and derivatives thereof, or pyromellitic diimide and derivatives thereof, but is not limited thereto.

The source and drain electrodes 314a and 314b are respectively formed on the organic semiconductor layer 315. The source and drain electrodes 314a and 314b may overlap with a portion of the gate electrode 312 as shown in FIG. 6, but are not limited thereto. The source and drain electrodes 314a and 314b may be the electrode as described above. Alternatively, the source and drain electrodes 314a and 314b may include a noble metal having a work function of 5.0 eV or more, for example, gold (Au), palladium (Pd), platinum (Pt), nickel (Ni), rhodium (Rh), ruthenium (Ru), iridium (Ir), osmium (Os), or a combination of at least two thereof in consideration of a work function of the material used to form the organic semiconductor layer 315.

Electronic devices have been described above with reference to FIGS. 4 to 6, but are not limited thereto.

### EXAMPLES

### Example 1

### Preparation of Graphene-Containing Layer

A graphene-containing layer was formed on a poly(ethylene terephthalate) (PET) substrate according to the following method.

Formation and Transfer of Monolayer Graphene

A Cu-foil having a size of 9 cm×15 cm was installed in a tubular furnace, heated to 1000° C. at 90 mtorr while supplying H₂ (8 s.c.c.m), and maintained at the same temperature for 30 minutes to form copper grains on the Cu-foil. Then, CH₄ (24 s.c.c.m) and H₂ (8 s.c.c.m) were supplied thereto at 460 mtorr for 30 minutes, and the Cu-foil was cooled to room temperature while supplying H₂ at 90 mtorr to form a monolayer graphene on the Cu-foil.

Then, polymethacrylate (PMMA) was pressurized onto the monolayer graphene to contact the PMMA with the monolayer graphene. A Cu-foil/monolayer graphene/PMMA film was immersed in a 98% ammonium persulfate solution, as an etchant of copper for 300 to 360 minutes and washed with deionized water to remove the Cu-foil, so that a monolayer graphene/PMMA film was obtained.

Then, the monolayer graphene/PMMA layer was disposed on the PET substrate such that the monolayer graphene contacts with the PET substrate. Then, the PMMA layer was pressurized at about 100° C. to transfer the monolayer graphene onto the PET substrate.

### Preparation of Multilayer Graphene

The process of transferring the monolayer graphene was repeated twice, three times, and four times to respectively form a bilayer graphene (G2), a trilayer graphene (G3) and a tetralayer graphene (G4) on the PET substrate, wherein the monolayer graphene from the second process is transferred to the previously transferred monolayer graphene).

### Doping of Graphene-Containing Layer Using HNO₃

As described above, after respectively preparing the PET/G2 film, the PET/G3 film, and the PET/G4 film, these films were immersed in a HNO₃ solution (MATSUNOEN CHEMICALS CO., Ltd., nitric acid 60%, FW 53.01) for 15 seconds and collected, and nitric acid was removed from the surface of graphene by nitrogen blowing. Then, the films were maintained in a vacuum for 30 minutes to respectively form graphene-containing layers doped with HNO₃ on the PET substrate respectively referring to “G2-HNO₃”, “G3-HNO₃”, and “G4-HNO₃”.

Doping of Graphene-Containing Layer Using AuCl₃

As described above, after respectively preparing the PET/G2 film, the PET/G3 film, and the PET/G4 film, these films were immersed in a solution prepared by dissolving AuCl₃ (KJIMA CHEMICALS Co. Ltd, FW=303.33) in nitromethane (99.0%, CH₃NO₂=61.04, Assay≧99.0%, SAMCHUN PURE CHEMICAL Co., Ltd.) to a 0.025 M for 1 minute and sonicated for 1 minute, and AuCl₃ was removed from the surface of graphene by nitrogen blowing. Then, the films were maintained in a vacuum for 30 minutes to respectively form graphene-containing layers doped with AuCl₃ on the PET substrate respectively referring to “G2-AuCl₃”, “G3-AuCl₃”, and “G4-AuCl₃”.

### Evaluation Example 1

### Evaluation of Characteristics of Graphene-Containing Layer

Optical transmittance of G2, G3, and G4 formed on the PET substrate prepared in Example 1 was evaluated using an UV-spectrometer (SCINCO (S-3100)), and the results are shown in FIG. 7. Referring to FIG. 7, the G2, G3 and G4 prepared in Example 1 had excellent transmittance of blue light.

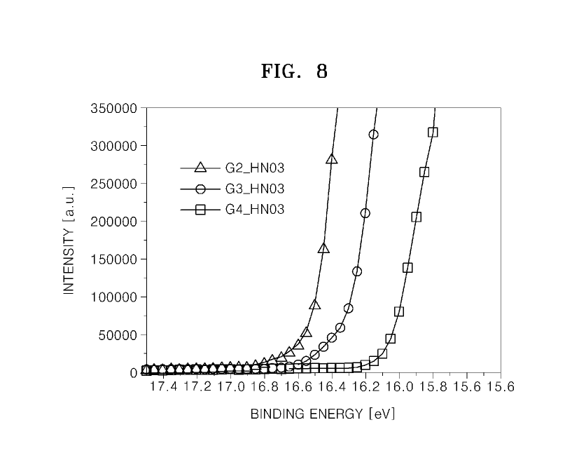

Meanwhile, binding energy and work function of the graphene-containing layer prepared in Example 1 were evaluated using an ultraviolet photoelectron spectroscopy (UPS), manufactured by VG Scientific (Model No. ESCALAB 220iXL), and the results are shown in FIG. 8 and Table 1. Sheet resistance of the graphene-containing layer prepared in Example 1 was evaluated using a KEITHLEY 2612, and the results are shown in Table 1.

TABLE 1

| | | | Material used | | |
|---|---|---|---|---|---|
| Graphene- | | No. of | for doping of | Work | Sheet |
| containing | Sub- | graphene | graphene- | function | resistance |
| layer | strate | layer | containing layer | (eV) | (ohm/sq) |
| G2 | PET | 2 | — | 4.32563 | 313 |
| G3 | PET | 3 | — | 4.37176 | 231.03 |
| G4 | PET | 4 | — | 4.44835 | 221.97 |
| G2-HNO₃ | PET | 2 | HNO₃ | 4.32054 | 165.35 |
| G3-HNO₃ | PET | 3 | HNO₃ | 4.46764 | 120.05 |
| G4-HNO₃ | PET | 4 | HNO₃ | 4.61767 | 104.19 |
| G2-AuCl₃ | PET | 2 | AuCl₃ | Not | Not |
| | | | | measured | measured |
| G3-AuCl₃ | PET | 3 | AuCl₃ | Not | Not |
| | | | | measured | measured |
| G4-AuCl₃ | PET | 4 | AuCl₃ | 5.07648 | 34.34 |

Referring to FIG. 8 and Table 1, as the number of graphene layer increased in the graphene-containing layer, work function of the graphene-containing layer increased and sheet resistance of the graphene-containing layer decreased. The doped graphene-containing layer had higher work function and lower sheet resistance than an undoped graphene-containing layer.

### Example 2

### Preparation of Anode

A G2-HNO₃, G3-HNO₃, G4-HNO₃, and G4-AuCl₃, as graphene-containing layers, were respectively formed on the PET substrate in the same manner as in Example 1.

Then, a poly(3,4-ethylenedioxythiophene):poly(styrenesulfonate)(PEDOT:PSS) aqueous solution (CLEVIOS™ P VP Al4083), wherein the content of PSS per 1 part by weight of PEDOT was 6 parts by weight, was mixed with a solution prepared by dispersing a material of Formula 100 below in a mixture of water and alcohol (water:alcohol=4.5:5.5 (v/v), 5% by weight, Aldrich Co.). In this regard, the ratio of the PEDOT:PSS aqueous solution and the solution including the material of Formula 100 was adjusted such that the content of the material of Formula 100 per 1 part by weight of PEDOT was 25.4 parts by weight.

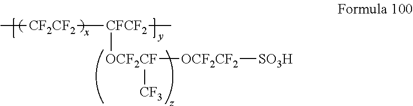

In Formula 100, x=1300, y=200, and z=1.

The mixture was spin-coated on the graphene-containing layer and heat-treated at 150° C. for 30 minutes to form a layer having work function gradient having a thickness of 50 nm. Thus, Anodes 1, 2, 3, and 4 including the graphene-containing layer and the layer having work function gradient having the structures shown in Table 2 below were formed on the PET substrate.

TABLE 2

| Anode | Sub- | Graphene- | Layer having work function |
|---|---|---|---|
| No. | strate | containing layer | gradient (w/w/w) |
| Anode 1 | PET | G2-HNO₃ | PEDOT/PSS/Material of Formula |
| | | | 100 (1/6/25.4) |
| Anode 2 | PET | G3-HNO₃ | PEDOT/PSS/Material of Formula |
| | | | 100 (1/6/25.4) |
| Anode 3 | PET | G4-HNO₃ | PEDOT/PSS/Material of Formula |
| | | | 100 (1/6/25.4) |
| Anode 4 | PET | G4-AuCl₃ | PEDOT/PSS/Material of Formula |
| | | | 100 (1/6/25.4) |

### Evaluation Example 2

### Evaluation of Characteristics of Anode

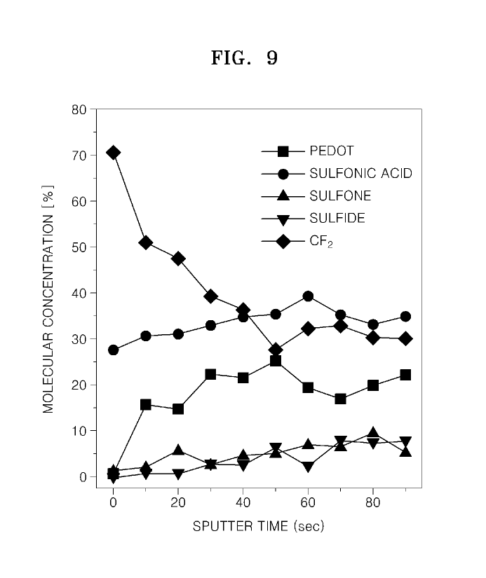

Molecular concentrations of Anode 4 with respect to depth of Anode 4, i.e., with respect to sputter time, were evaluated using X-ray photoelectron spectroscopy (XPS, manufactured by VG Scientific, Model No. ESCALAB 220iXL), and the results are shown in FIG. 9. In this regard, deconvoluted S2p peak for concentrations of PEDOT (164.5 eV), sulfonic acid (168.4 and 168.9 eV), sulfide (162 eV), and sulfone (166.6 eV) and C1s peak for the material of Formula 100 (291.6 eV) were analyzed in the XPS spectrum, so that concentrations thereof were evaluated. Referring to FIG. 9, the concentration of CF₂ moiety indicating the concentration of the low-surface-energy material of Formula 100 substantially decreased and the concentration of PEDOT substantially increased in a direction from the surface of the layer having work function gradient of Anode 4, i.e., the second surface of the layer having work function gradient, (sputter time=0) to the graphene-containing layer, i.e., the first surface of the layer having work function gradient. Thus, materials contained in the layer having work function gradient of Anode 4 were not homogeneously distributed, but had a concentration gradient that changes with respect to the depth of the layer having work function gradient.

Meanwhile, work function of the surface, i.e., the second surface, of the layer having work function gradient, of Anode 4 which was measured in the same manner as in Evaluation Example 1 was 5.95 eV.

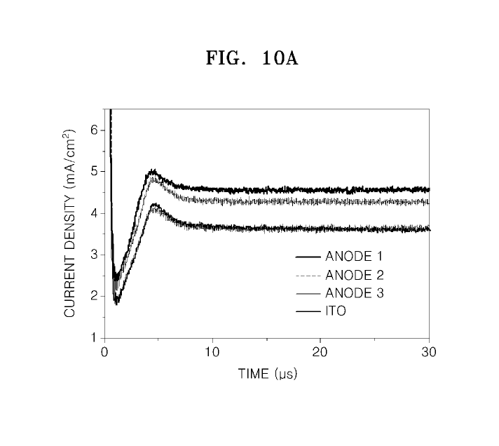

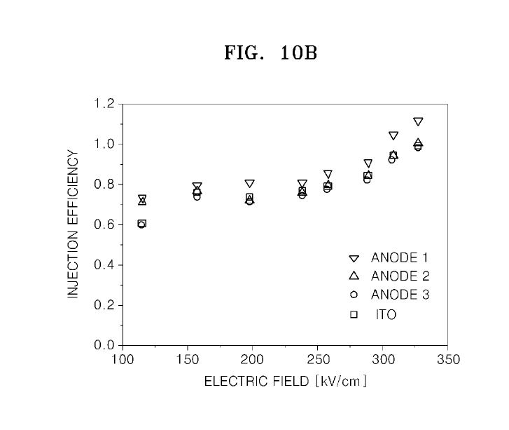

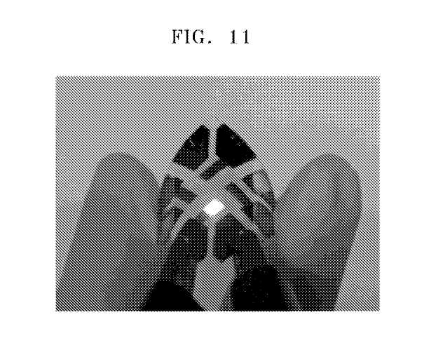

Then, hole injection efficiencies of Anodes 1, 2, and 3 were evaluated, and the results are shown in FIG. 10A (electric field-current density graph) and FIG. 10B (electric field-hole injecting efficiency graph). Dark injection space-charge-limited-current (DI SCLC) transients were used when the hole injection efficiency was measured. A hole-only device having an anode (Anodes 1, 2, or 3)/NPB layer (about 2.6 μm)/Alstructure was prepared and the DI SCLC transients were performed. While the DI SCLC transients were performed, a pulse generator (HP 214B) and a digital oscilloscope (Agilent lnfiniium 54832B) were used. Referring to FIGS. 10A and 10B, Anodes 1, 2, and 3 had excellent hole injection efficiency.

### Example 3

### Evaluation of Characteristics of Oled Emitting Green Light

Anodes 1, 2, 3, and 4 were respectively formed on the PET substrate in the same manner as in Example 2. Anodes 1, 2, 3, and 4 were patterned by a reactive ion etching using oxygen plasma. An NPB HTL having a thickness of 20 nm, a Bebq₂:C545T EML having a thickness of 20 nm, wherein the content of C545T was 1.5% by weight, a Bebq₂ ETL having a thickness of 20 nm, a Liq ETL having a thickness of 1 nm, and an Al cathode having a thickness of 130 nm were sequentially formed on Anodes 1, 2, 3, and 4 by vacuum deposition to prepare an OLED, wherein the area of an emission region was 2×3 mm². Hereinafter, OLEDs respectively employing Anodes 1, 2, 3, and 4 refer to OLEDs 1, 2, 3, and 4.

### Comparative Example A

A G4-AuCl₃ was formed on the PET substrate as an anode in the same manner as in Example 1, i.e., the anode of Comparative Example A does not include a layer having work function gradient. Then, PEDOT:PSS (CLEVIOS™ P VP Al4083), wherein the content of PSS per 1 part by weight of PEDOT was 6 parts by weight was spin-coated on the G4-AuCl₃ to a thickness of 50 nm and heat treated at 150° C. for 30 minutes. Then, an NPB HTL having a thickness of 20 nm, a Bebq₂:C545T EML having a thickness of 20 nm, wherein the content of C545T was 1.5% by weight, a Bebq₂ ETL having a thickness of 20 nm, a Liq ETL having a thickness of 1 nm, and an Al cathode having a thickness of 130 nm were sequentially formed thereon by vacuum deposition to prepare OLED A.

### Comparative Example B

OLED B was prepared in the same manner as in Comparative Example A, except that the PEDOT:PSS HTL having a thickness of 50 nm was not formed.

### Comparative Example C

OLED C was prepared in the same manner as in Comparative Example A, except that a Corning 15 Ω/cm² (1200 Å) ITO glass substrate was used as the anode instead of G4-AuCl₃ formed on the PET substrate.

### Comparative Example D

OLED D was prepared in the same manner as in Comparative Example C, except that the PEDOT:PSS HTL having a thickness of 50 nm was not formed.

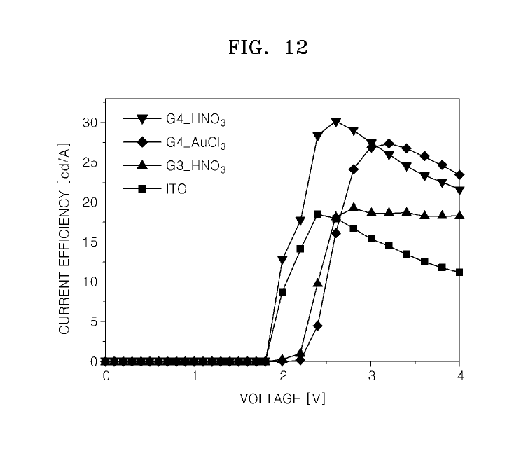

Structures and flexibility of OLEDs 1 to 4 and A to D were shown in Table 3 below (O: flexible/X: unable to bend). In this regard, flexibility of OLED 4 is shown in FIG. 11.

TABLE 3

| OLED | Sub- | | Flex- |
|---|---|---|---|
| No. | strate | Anode | ible |
| 1 | PET | Anode 1 | ◯ |
| | | (G2-HNO₃ + Layer having work | |
| | | function gradient) | |
| 2 | PET | Anode 2 | ◯ |
| | | (G3- HNO₃ + Layer having work | |
| | | function gradient) | |
| 3 | PET | Anode 3 | ◯ |
| | | (G4- HNO₃ + Layer having work | |
| | | function gradient) | |
| 4 | PET | Anode 4 | ◯ |
| | | (G4-AuCl₃+ Layer having work | |
| | | function gradient) | |
| A | PET | G4-AuCl₃ | ◯ |
| B | PET | G4-AuCl₃ | ◯ |
| C | Glass | ITO | X: |
| D | Glass | ITO | X: |

### Evaluation Example 3

### Preparation of OLED Emitting Green Light

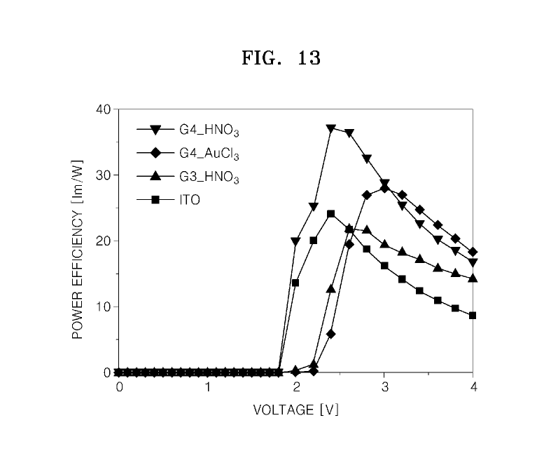

Current efficiency, power efficiency, and EL spectrum of OLEDs 1, 2, 3, 4, A, B, C and D were evaluated using a Keithley 236 source measure unit and a Minolta CS 2000 spectroradiometer, and the results are shown in FIGS. 12 and 13. Referring to 12 and 13, the OLED having the 4-layered graphene had the highest efficiency.

### Example 4

### Preparation of OLED Emitting White Light

Anode 3 was formed on the PET substrate in the same manner as in Example 2. Anode 3 was patterned by a reactive ion etching using oxygen plasma. An NPB HTL having a thickness of 20 nm, an NPB:TBADN:rubrene first EML having a thickness of 10 nm, wherein the content of rubrene was 1% by weight, and NPT:TBADN:DPAVBi second EML having a thickness of 10 nm, wherein the content of DPAVBi was 5% by weight, a TBADN:DPAVBi third EML having a thickness of 15 nm, wherein the content of DPAVBi was 5% by weight, a Bebq₂ ETL having a thickness of 20 nm, a BaF₂ ELT having a thickness of 1 nm, and an Al cathode having a thickness of 130 nm were sequentially formed on Anode 3 by vacuum deposition to prepare OLED 5.

### Comparative Example E

OLED E was prepared in the same manner as in Example 5, except that a Corning 15 Ω/cm² (1200 Å) ITO glass substrate was used as the anode instead of Anode 3 formed on the PET substrate.

### Evaluation Example 4

### Evaluation of Characteristics of OLED Emitting White Light

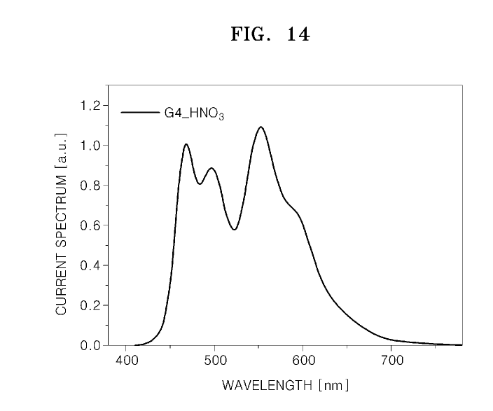

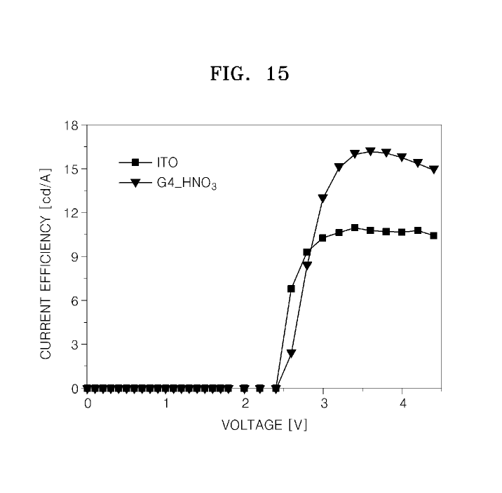

Current efficiency of OLEDs 5 and E and EL spectrum of OLED 5 were evaluated, and the results are shown in FIGS. 14 and 15. Referring to FIG. 14, OLED 5 had better current efficiency than OLED E. Meanwhile, CIE color coordinates of OLED 5 were (0.32, 0.42) indicating excellent color purity.

As described above, according to the one or more of the above embodiments of the present invention, due to excellent mechanical strength, durability, chemical resistance, and conductivity, and high work function, the electrode may be efficiently applied to various electronic devices. Due to flexibility, the electrode may also be applied to flexible electronic devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An electrode comprising:
a graphene-containing layer; and
a layer having work function gradient formed on the graphene-containing layer;
wherein the layer having work function gradient is a single layer comprising a first surface that contact with the graphene-containing layer and a second surface that is opposite to the first surface, wherein a work function of the layer having work function gradient gradually increase in a direction from the first surface of the layer having work function gradient to the second surface of the layer having work function gradient.

2. The electrode of claim 1, wherein the graphene comprise n sheets, each of which is formed of polycyclic aromatic molecules in which a plurality of carbon atoms are bonded to each other in a covalent bond and extend in a first direction (i.e., a direction parallel to the substrate), wherein n is an integer of 1 or greater.

3. The electrode of claim 2, wherein n is 2 or more, and the n sheets are stacked in a second direction perpendicular to the first direction.

4. The electrode of claim 2, wherein n is an integer from 2 to 10.

5. The electrode of claim 1, wherein the graphene-containing layer further comprises a p-type dopant.

6. The electrode of claim 5, wherein the p-type dopant comprises HNO₃, AuCl₃, HCl, nitromethane, H₂SO₄, HAuCl₄, 2,3-dichloro-5,6-dicyanobenzoquinone, acid-terminated small molecules, polymeric acid, or a combination of at least two thereof.

7. The electrode of claim 1, wherein a work function of the first surface of the layer haying work function gradient is in the range of 4.8 eV to 5.3 eV, and a work function of the second surface of the layer having work function gradient is in the range of 5.3 eV to 6.5 eV.

8. The electrode of claim 1, wherein the layer having work function gradient comprises a conductive material and a low-surface-energy material.

9. The electrode of claim 8, the low-surface-energy material satisfies as follows: a thin film formed of the low-surface-energy material has a surface energy of 30 mN/m or less and a conductivity in the range of 10⁻¹⁵ to 10⁻¹ S/cm or a thin film formed of a conductive polymeric composition comprising the low-surface-energy material has a surface energy of 30 mN/m or less and a conductivity in the range of 10⁻⁷ to 10⁻¹ S/cm.

10. The electrode of claim 8, wherein the concentration of the low-surface-energy material gradually increases in a direction from the first surface to the second surface.

11. The electrode of claim 8, wherein a work function of the first surface of the layer having work function gradient is the same as that of the conductive material, and a work function of the second surface of the layer having work function gradient is the same as that of the low-surface-energy material.

12. The electrode of claim 8, wherein the low-surface-energy material comprises at least one fluorine (F).

13. The electrode of claim 8, wherein the low-surface-energy material is a fluorinated polymer having a repeating unit represented by one of Formulae 1 to 3 below: 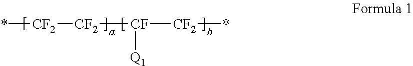
wherein a is a number from 0 to 10,000,000;
b is a number from 1 to 10,000,000; and
Q₁ is —[O—C(R₁)(R₂)—C(R₃)(R₄)]_{c}—[OCF₂CF₂]_{d}—R₅, —COOH, or —O—R_{f}—R₆;
wherein R₁, R₂, R₃ and R₄ are each independently —F, —CF₃, —CHF₂ or —CH₂F;
c and d are each independently a number from 0 to 20;
R_{f} is —(CF₂)_{z}— or —(CF₂CF₂O)_{z}—CF₂CF₂—, wherein z is an integer from 1 to 50; and
R₅ and R₆ are each independently —SO₃M, —PO₃M₂, or —CO₂M;
wherein M is Na⁺, K⁺, Li⁺, CH₃(CH₂)_{w}NH₃⁺, NH₄⁺, NH₂⁺, NHSO₂CF₃⁺, CHO⁺, C₂H_{S}OH⁺, CH₃OH⁺, or CH₃(CH₂)_{w}CHO⁺, wherein w is an integer from 0 to 50, 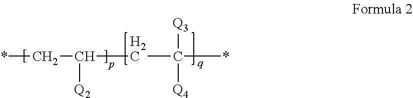
wherein Q₂ is a hydrogen atom, a substituted or unsubstituted C₅-C₆₀ aryl group, or —COOH;
Q₃ is a hydrogen atom or a substituted or unsubstituted C₁-C₂₀ alkyl group; and
Q₄ is —O— (CF₂)ᵣSO₃M, —O—(CF₂)ᵣPO₃M₂, —O—(CF₂)ᵣ—CO₂M, or —CO—NH—(CH₂)ₛ—(CF₂)ₜ—CF₃,
wherein r, s and t are each independently a number from 0 to 20; and
M is Na⁺, K⁺, Li⁺, H⁺, CH₃(CH₂)_{w}NH₃⁺, NH₄⁺, NH₂⁺, NHSO₂CF₃⁺, CHO⁺, C₂H₅OH⁺, CH₃OH⁺, or CH₃(CH₂)_{w}CHO⁺, wherein w is an integer from 0 to 50, and 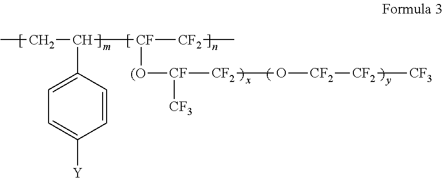
wherein 0≦m<10,000,000, and 0<n≦10,000,000;
x and y are each independently a number from 0 to 20; and
Y is —SO₃M, —PO₃M₂, or —CO₂M;
wherein M is Na⁺, K⁺, Li⁺, H⁺, CH₃(CH₂)_{w}NH₃⁺, NH₄⁺, NH₂⁺, NHSO₂CF₃⁺, CHO⁺, C₂H₅OH⁺, CH₃OH⁺, or CH₃(CH₂)_{w}CHO⁺, wherein w is an integer from 0 to 50.

14. The electrode of claim 8, wherein the low-surface-energy material is a fluorinated oligomer represented by Formula 10 below:
X-M^{f}ₙ-M^{h}ₘ-M^{a}ᵣ-G Formula 10
wherein X is a terminal group;
M^{f} is a unit derived from a fluorinated monomer prepared by condensation reaction of perfluoropolyether alcohol, polyisocyanate, and an isocyanate reactive-non-fluorinated monomer;
M^{h} is a unit derived from a non-fluorinated monomer;
M^{a} is a unit having a silyl group represented by —Si(Y₄)(Y₅)(Y₆),
wherein, Y₄, Y₅ and Y₆ are each independently a halogen atom, a substituted or unsubstituted C₁-C₂₀ alkyl group, a substituted or unsubstituted C₆-C₃₀ aryl group, or a hydrolysable substituent, wherein at least one of the Y₄, Y₅ and Y₆ is a hydrolysable substituent,
G is a monovalent organic group including a chain transfer agent;
n is a number from 1 to 100,
m is a number from 0 to 100, and
r is a number from 0 to 100,
wherein n+m+r≧2.

15. The electrode of claim 8, wherein the conductive material comprises polythiophene, polyaniline, polypyrrole, polystyrene, sulfonated polystyrene, poly(3,4-ethylenedioxythiophene), self-doped conductive polymer, any derivative thereof, or any combination thereof.

16. An electronic device comprising an electrode according to claim 1.

17. The electronic device of claim 16, wherein the electronic device has flexibility.

18. The electronic device of claim 16, wherein the electronic device comprises an organic light-emitting device, an organic solar cell, an organic memory device, or an organic thin film transistor.
